(19) United States
(12) Patent Application Publication
(10) Pub. No.: US 2012/0026019 A1
(43) Pub. Date: Feb. 2, 2012

(54) DRIVING CIRCUIT OF LIGHT EMITTING DIODE, DECODING CIRCUIT AND DECODING METHOD THEREOF

(75) Inventors: CHUN-FU LIN, Hsinchu City (TW); Chun-Ting Kuo, Pingtung County (TW); Cheng-Han Hsieh, Hsinchu County (TW)

(73) Assignee: MY-SEMI INC., Hsinchu County (TW)

(21) Appl. No.: 13/103,819

(22) Filed: May 9, 2011

(30) Foreign Application Priority Data
Jul. 30, 2010 (TW) 99125391

(51) Int. Cl. H03M 7/00; H05B 37/02

(52) U.S. Cl. 341/50; 315/291

(57) ABSTRACT

A driving circuit, a decoding circuit and a decoding method thereof are provided. The decoding circuit includes an oscillator and a decoder including a frequency determining unit and a decoding unit. The frequency determining unit receives a clock signal and a data signal which is corresponding to DMX512 protocol, and samples one slot of the data signal according to the clock signal to generate a sample number corresponding to a slot period of the slot. Then, the frequency determining unit outputs a reference signal corresponding to the frequency of the clock signal according to the sample number. The decoding unit samples the data signal according to the clock signal and the reference signal to decode data carried on the data signal. The decoding circuit is able to sample the data signal correctly without disposing any external frequency adjusting element.

### BACKGROUND OF THE INVENTION

1. Field of the Invention

The present invention relates to a DMX512 decoding circuit, and more particularly, to a driving circuit of light emitting diode (LED), decoding circuit and decoding method thereof.

2. Description of Related Art

DMX512 indicates a standard for digital communication interface which is largely used as a communication protocol between lighting devices and comprises the data format for data transmissions, the electrical feature of devices and the connector type. The DMX512 protocol was initially developed under the Engineering Commission of United States Institute for Theatre Technology (USITT). In fact, before the introduction of the DMX512 protocol, several light control protocols had been developed for the lighting devices; however, as the lighting devices/systems become more and more complicated, the conventional protocols may not offer the most suitable solutions, prompting the introduction of the DMX512 protocol.

The transmission of DMX512 data takes a form of asynchronous serial format, with each data packet including a START CODE and at most 512 channel data, in which the first slot (slot0) is used to transmit the START CODE, and the subsequent slots from the second slot (slot1) to the 512^{th} slot (slot512) are designated to channel data transmissions.

At the present, the DMX512 data format is commonly used for editing program files applied in international or domestic computer lights. The speed of DMX512 data flow is 250K; that is, each bit is associated with a period of 4 microseconds which falls within the range of 3.92 microseconds to 4.08 microseconds specified in the protocol. Since the DMX512 data signal is a transmission protocol employing the high/low level combination of precise time periods, accurate sampling reference frequencies are required in order to correctly decode the 8-bit data residing in the DMX data signal. However, due to limitations on processes and design costs, it is uncommon to directly install the oscillator of high precision in the chip simply for the purpose of satisfying the needs in the DMX decoder. Consequently, in prior art, the DMX512 decoder usually requires either the installation of external elements (e.g., capacitor) for adjusting the oscillation frequency of internal clock signals, or otherwise an external connection directly to the oscillator of the high precision. Unfortunately either arrangement may complicate the entire circuitry design, and increase the corresponding manufacturing cost as well.

### SUMMARY OF THE INVENTION

The present invention provides a decoding circuit and driving circuit which enables a function of internal detections on the frequency of the clock signal, thereby spontaneously adjusting the sampling frequency based on the detected frequency of the clock signal in order to correctly decode the DMX512 data signal.

The present invention provides a decoding method which uses the DMX data signal to estimate the frequency of the clock signal inside the chip, and decodes the DMX data signal according to the correct sampling reference frequency.

One embodiment of the present invention provides a decoding circuit comprising an oscillator and a decoder further including a frequency determining unit and a decoding unit. The oscillator outputs a clock signal, and the decoder is coupled to the oscillator and receives the clock signal and a data signal. The data signal may be associated with a plurality of slots each corresponds to a slot period. The decoder samples one of the slots based on the clock signal to generate a sample number corresponding to the slot period of the slot and calculates the frequency of the clock signal according to the sample number, and then decodes the data carried by the data signal according to the frequency of the clock signal.

Herein the frequency determining unit is coupled to the oscillator and receives the clock signal and the data signal. The frequency determining unit samples one of the slots based on the clock signal to generate a sample number corresponding to the slot period of the slot and outputs a reference signal corresponding to the frequency of the clock signal according to the sample number. The decoding unit is coupled to the frequency determining unit and the oscillator. The decoding unit samples the data signal based on the clock signal and the reference signal to decode the data carried by the data signal.

In one aspect of the present invention, the format of the aforementioned data signal corresponds to the DMX512 protocol, and the frequency determining unit samples a first slot of the slots to generate the sample number. Herein the first slot has a start code or a default code.

In another aspect of the present invention, the aforementioned frequency determining unit samples at least one bit in the first slot based on the clock signal to generate the above-said sample number.

The present invention also provides a driving circuit of light emitting diode (LED). The driving circuit includes the decoding circuit and the driving unit described as above, in which the driving circuit is coupled to the decoding circuit and outputs an LED driving signal according to the data carried on the data signal.

The present invention further provides a decoding method for decoding a data signal corresponding to the DMX512 protocol. The decoding method includes receiving a clock signal and a data signal associated with a plurality of slots each corresponds to its respective slot period, sampling one of the slots based on the clock signal to generate a sample number corresponding to the slot period, outputting a reference signal corresponding to the frequency of the clock signal according to the sample number, and sampling the data signal according to the clock signal and the reference signal to decode the data carried by the data signal. Other implementation details of the present decoding method may be referred to the descriptions of the decoding circuit illustrated as above and herein omitted for the sake of compact prosecution of the instant patent application.

In summary, the driving circuit of light emitting diode, decoding circuit and decoding method thereof according to the present invention enable internal detections on the frequency of the clock signal, thereby spontaneously adjusting the sampling frequency based on the detected oscillation frequency in order to correctly sample the DMX512 data signal. Through the architecture proposed by the present invention, the decoding circuit and the driving circuit may sample the data signal by clock signals of different frequencies without additionally employing external frequency adjusting elements so that the frequency drift in the oscillator caused by process variations or poor designs is overcome.

To facilitate better appreciation of the aforementioned characteristics and advantages of the present invention, detailed descriptions are illustrated hereunder with preferred embodiments thereof in conjunction with appended drawings.

### BRIEF DESCRIPTION OF THE DRAWINGS

FIG. 1 shows a diagram of the frequency estimation for a clock signal according to a first embodiment of the present invention;

FIG. 2 shows a diagram of an LED driving circuit according to the first embodiment of the present invention; and

FIG. 3 shows a flowchart of the decoding method according to a second embodiment of the present invention.

### DETAILED DESCRIPTION OF THE PREFERRED EMBODIMENTS

### First Embodiment

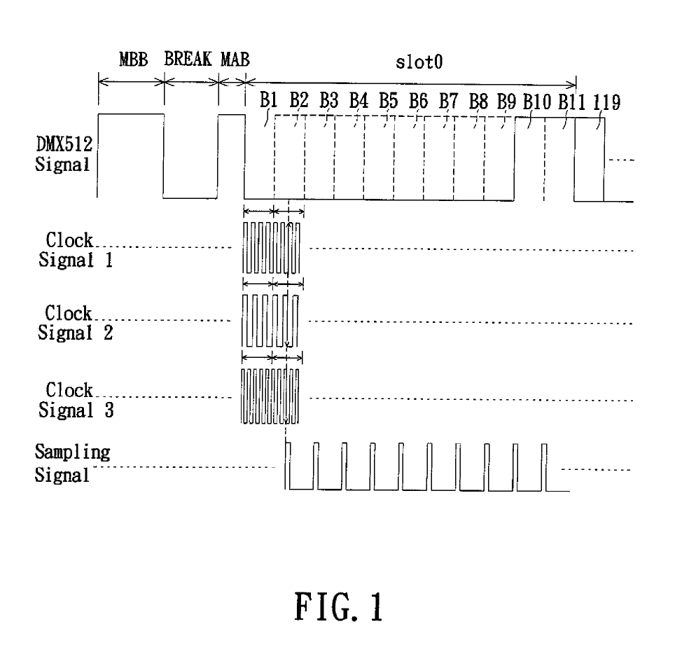

Refer to FIG. 1, wherein a diagram of the frequency estimation for a clock signal according to a first embodiment of the present invention is shown. The DMX512 signal includes a break (“BREAK”), a “Mark time after BREAK” (MAB), a start code (located at the first slot (slot0)), channel data (located among the second slot (slot1) to the 513^{th} slot (slot512). In one implementation, the slots from the second slot (slot1) to the 513^{th} slot (slot512) follow the first slot (slot0), which is not shown in FIG. 1. A “Mark time between slots” 119 and a “Mark time before BREAK” (MBB). BREAK indicates the start of a DMX512 data packet, which is a low-level output of 88 microseconds, and is followed by MAB, which is a high-level output of 8 microseconds or two 4-microsecond high-level pulses. The start code (SC) represents the start for the data flow, which has the same format as the channel data and usually includes 11 bits or lasts for 44 microseconds. In the DMX512 protocol, the standard time period for each bit in the channel data is 4 microseconds, while the standard range specified by the protocol is between 3.92 microseconds to 4.08 microseconds.

As illustrated above, the slot period for each slot (slot0˜slot 512) is 44 microseconds, which is equivalent to 11 bits of the data flow (or the channel data). Take the first slot (slot0) for example, its first bit B1 is the low-level start bit, the 2^{nd}˜9^{th} bits B2 to B9 are data bits, and the 10^{th}˜11^{th} bits B10 and B11 indicate the high-level stop bits. In one implementation, the format in each of the 2^{nd}˜513^{th} slots (slot1˜slot 512) is substantially identical to the first slot (slot0). The interval between two subsequent slots is the “Mark time between slots” 119 of a duration between 0 to 1 second. In one implementation, the duration of the MAB is between 8 microseconds to 1 second with the duration of the MBB ranging between 0˜1 second.

It can be seen from the aforementioned specifications that, in a DMX512 data packet, only the slot period is fixed, while other periods may vary significantly. Accordingly, the time period of the slot may be utilized to derive the frequency of the sampling signal (i.e., the clock signal of the oscillator within the chip). Refer again to FIG. 1, wherein the clock signal 1, the clock signal 2, and the clock signal 3 correspond to different sampling frequencies. When sampling the bits B1 and B2 in the first slot (slot0) on basis of the clock signal 1, the sample number between the time period of the two bits (8 microseconds, that is, 2/11 of the time period of the first slot (slot0)) is 8, e.g., 8 pulses. Accordingly, the frequency of the clock signal 1 may approximately stand at 500 KHz. The frequencies of the clock signal 1 and the clock signal 2 may be estimated by the same approach. Upon sampling the bits B1 and B2 in the first slot (slot0) according to the clock signal 2, the sampling number may become 6, and the estimated frequency of the clock signal 2 may approximately stand at 300 KHz. Meanwhile, when sampling the bits B1 and B2 on basis of the clock signal 3, the sampling number may become 10, and the estimated frequency of the clock signal 3 may approximately stand at 625 KHz.

As the frequency of the currently used clock signal may be accurately estimated, that clock signal may be employed to sample and decode subsequent slots. It is worth noting that in order to accurately identify the time period associated with the bits B1 and B2, in one implementation the 3^{rd} bit (i.e., B3) may be set to “high,” differentiating B3 from B1 and B2, both of which may be set to “low.” In another implementation, a predetermined waveform may be incorporated into the 1^{st} slot (slot0) (for example, a predetermined data type or default code such as the data of 00000000) so that the entire time period of slot0 may be utilized for determining the frequencies of the clock signals 1 to 3.

Additionally, in another implementation any bit in addition to the combination of B1 and B2 in the 1^{st} slot (slot0), or any slot in the slot 1 to the slot 512 may be utilized to derive the frequencies of the clock signals 1 to 3. Since the time period of each slot (or bits therein) may remain unchanged, the frequency of the currently used clock signal may be derived so long as the sampling period of the clock signal is determined. Through teachings of the aforementioned embodiment, other embodiments can be conveniently deduced by those skilled ones in the art and herein are not further discussed.

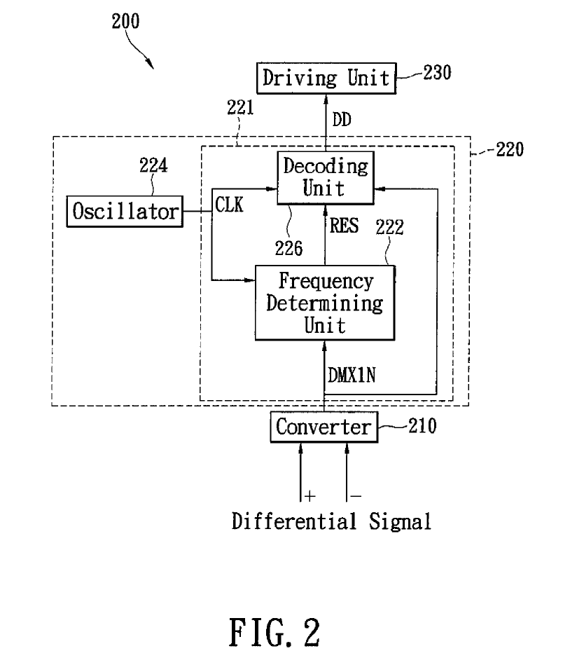

After acquisition of the frequency of the clock signal within the chip, the system may further determine a sampling frequency of a sampling clock to be used. The bit such as B1 or B2 may be accurately sampled so long as sampling points of the sampling clock is located at a midpoint of the time period of the bit to be sampled. The above-said approach can be directly applied to the DMX512 decoding circuit and LED driving circuit. Refer now to FIG. 2, wherein a diagram of an LED driving circuit according to the first embodiment of the present invention is shown. The driving circuit 200 essentially comprises a decoding circuit 220 and a driving unit 230. The decoding circuit 220 further includes a decoder 221 and an oscillator 224. The decoder 221 includes a frequency determining unit 222 and a decoding unit 226. The decoder 221 is coupled to the oscillator 224 and receives a clock signal CLK and a data signal DMXIN. The decoder 221 is configured to sample a slot in the data signal DMXIN based on the clock signal CLK and then calculate the frequency of the clock signal CLK by using a sample number and a known time period of the slot. Next, the data within the remaining slots of the data signal DMXIN may be decoded with the clock signal CLK according to the frequency of the clock signal CLK.

The circuitry structure and operations of the decoding circuit 220 including the frequency determining unit 222, oscillator 224 and decoding unit 226 will now be further explained. The decoding unit 226 is coupled between the frequency determining unit 222 and the driving unit 230, and the oscillator 224 is coupled to the frequency determining unit 222 and the decoding unit 226. A converter 210 is coupled to the frequency determining unit 222 for receiving external differential signals and converting the differential signals into the data signal DMXIN compliant with the DMX512 protocol. In one implementation, the converter 210 may be a RS485 converter.

The oscillator 224 outputs a clock signal CLK to the frequency determining unit 222 and the decoding unit 226 for the signal sampling purpose. The frequency determining unit 222 receives the data signal DMXIN and samples one of the slots (e.g., slot 0) in the data signal DMXIN based on the clock signal CLK before a sample number corresponding to the slot period may be generated. Thereafter, reference signal RES corresponding to the frequency of the clock signal in accordance with such a sample number may be outputted. The frequency determining unit 222 then estimates the frequency of the clock signal CLK through the approach set forth in the description related to FIG. 1.

After the frequency determining unit 222 estimates the frequency of the clock signal CLK, the decoding unit 226 samples the data signal DMXIN based on the clock signal CLK and the reference signal RES so as to decode the driver data (DD) carried by the data signal DMXIN, and then outputs the driver data (DD) to the driving unit 230 for driving an LED (not shown). The decoding unit 226 may determine a suitable sampling rate for sampling the data signal DMXIN according to the frequency of the clock signal CLK. Through such a type of circuitry architecture, the driving circuit 200 is capable of making adaptive adjustments automatically according to the frequency of the oscillator 224 to overcome the frequency drift problem associated with the oscillator. Therefore, the DMX512 driving chip or decoding chip incorporating the driving circuit 200 requires no externally added discrete frequency adjusting elements, e.g., a capacitor, for adjusting the frequency of the internal oscillator 224. The driving circuit 200 and the decoding circuit 220 according to the present invention may not only simplify the circuitry architecture but also further stabilize the system. Besides, it is worth noting that the decoding circuit 220 and the driving unit 230 may be integrated into the same chip.

Furthermore, in another embodiment of the present invention, the frequency determining unit 222 may directly generate the sampling clock to the decoding unit 226, which in turn utilizes the sampling clock for sampling the data signal DMXIN based on the sampling clock and decode the data carried by the data signal DMXIN. Of course, the decoder 221 may also generate the sampling clock directly according to the frequency information of the clock signal CLK. The circuitry architecture shown in FIG. 2 simply indicates an embodiment of the present invention and the circuitry architecture according to the present invention is by no means limited thereto.

In addition, it is also worth noting that the driving circuit 200 in the present embodiment may be applicable to the data signal of various versions of DMX512 protocol, such as the standard DMX512 protocol, 2×-speed DMX512 protocol or 4×-speed DMX512 protocol. 2×-speed DMX512 protocol means its specified time for the data format is reduced to ½ of that of the standard DMX512 protocol, thereby doubling the size of data transmission within the same duration of time. Similarly, the 4×-speed DMX512 protocol lessens its specified time for the data format to be ¼ of the counterpart of the standard DMX512 protocol so as to further increase the volume of the data transmission. Since the slots in each of these DMX512 protocols correspond to fixed time periods, the frequencies of the clock signals CLK may be derived accordingly.

### Second Embodiment

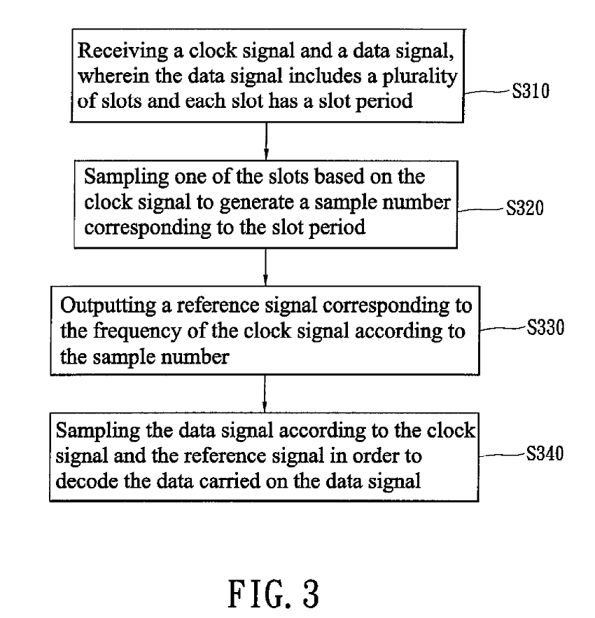

Refer now to FIG. 3, wherein a flowchart of the decoding method according to a second embodiment of the present invention is shown. The present decoding method is applicable to decoding a data signal in compliance with the DMX512 protocol. The decoding method includes receiving a clock signal and a data signal, wherein the data signal includes a plurality of slots and each slot is associated with a time period as shown in FIG. 1 (STEP S310), sampling one of the slots based on the clock signal to generate a sample number corresponding to the slot sampled (STEP S320), outputting a reference signal corresponding to the frequency of the clock signal according to the sample number (STEP S330), and sampling the data signal according to the clock signal and the reference signal in order to decode the data carried by the data signal (STEP S340). With descriptions for the aforementioned embodiment, other implementation details of the present decoding method may be deduced by those skilled ones in the art.

In summary, the present invention utilizes that the time period of the slot in the DMX512-compliant data signal (i.e., slot period) may remain fixed to estimate the frequency of the internal oscillator for determining the appropriate sampling frequency. Such a circuitry architecture and decoding method may overcome the frequency drift problem in the oscillator without the need of external frequency adjusting elements before accurate samplings of the DMX512-complaint data signal may be achieved. The present invention simplifies the circuitry architecture and further enhances the stability of the system.

Although the preferred embodiments of the present invention have been disclosed in previous texts, it should be noticed that the scope of the present invention is by no means limited thereto. Those skilled ones in the art can make effectively equivalent modifications and alternations to the embodiments disclosed as above without departing from the scope of the present invention. Therefore, the field of the present invention to be legally protected should be defined by the claims set forth hereunder.

What is claimed is:

1. A decoding circuit for decoding a data signal, comprising:
an oscillator for outputting a clock signal; and
a decoder, coupled to the oscillator, for receiving the clock signal and the data signal, the data signal including a plurality of slots, each slot having a slot period, wherein the decoder samples one of the slots based on the clock signal to generate a sample number corresponding to the slot period and calculates a frequency of the clock signal according to the sample number, and then decodes data of the data signal according to the frequency of the clock signal.

2. The decoding circuit according to claim 1, wherein the decoder further comprises:
a frequency determining unit, coupled to the oscillator, for receiving the clock signal and the data signal, wherein the frequency determining unit samples one of the slots based on the clock signal to generate the sample number corresponding to the slot period and outputs a reference signal corresponding to the frequency of the clock signal according to the sample number; and
a decoding unit, coupled to the frequency determining unit and the oscillator, wherein the decoding unit samples the data signal based on the clock signal and the reference signal to decode the data of the data signal.

3. The decoding circuit according to claim 1, wherein a format of the data signal is corresponding to a DMX512 protocol and the frequency determining unit samples a first slot of the slots to generate the sample number.

4. The decoding circuit according to claim 3, wherein the first slot has a start code.

5. The decoding circuit according to claim 2, wherein the frequency determining unit samples at least one bit in the first slot of the slots based on the clock signal to generate the sample number.

6. The decoding circuit according to claim 5, wherein the first slot has a default code.

7. The decoding circuit according to claim 2, wherein the oscillator, the frequency determining unit and the decoding unit are integrated in the same chip.

8. A driving circuit of light emitting diode (LED), comprising:
a decoding circuit, comprising:
an oscillator for outputting a clock signal; and
a decoder, coupled to the oscillator, for receiving the clock signal and a data signal, the data signal including a plurality of slots, each slot having a slot period, wherein the decoder samples one of the slots based on the clock signal to generate a sample number corresponding to the slot period of the slot and calculates a frequency of the clock signal according to the sample number, and then decodes data of the data signal according to the frequency of the clock signal; and
a driving unit, coupled to the decoding circuit, for outputting an LED drive signal according to the data of the data signal.

9. The driving circuit of LED according to claim 8, wherein the decoder comprises:
a frequency determining unit, coupled to the oscillator, for receiving the clock signal and the data signal, wherein the frequency determining unit samples one of the slots based on the clock signal to generate the sample number corresponding to the slot period of the slot and outputs a reference signal corresponding to the frequency of the clock signal according to the sample number; and
a decoding unit, coupled to the frequency determining unit and the oscillator, wherein the decoding unit samples the data signal based on the clock signal and the reference signal to decode the data of the data signal.

10. The driving circuit of LED according to claim 8, wherein the format of the data signal corresponds to the DMX512 protocol and the frequency determining unit samples a first slot of the slots to generate the sample number.

11. The driving circuit of LED according to claim 10, wherein the first slot has a start code.

12. The driving circuit of LED according to claim 9, wherein the frequency determining unit samples at least one bit in the first slot of the slots based on the clock signal to generate the sample number.

13. The driving circuit of LED according to claim 12, wherein the first slot has a default code.

14. The driving circuit of LED according to claim 9, wherein the oscillator, the frequency determining unit, the decoding unit and the driving unit are integrated into the same chip.

15. A decoding method suitable for decoding a data signal corresponding to a DMX512 protocol, the decoding method comprising:
receiving a clock signal and a data signal, wherein the data signal has a plurality of slots and each slot has a slot period;
sampling one of the slots based on the clock signal to generate a sample number corresponding to the slot period;
outputting a reference signal corresponding to a frequency of the clock signal according to the sample number; and
sampling the data signal according to the clock signal and the reference signal to decode data of the data signal.

16. The decoding method according to claim 15, wherein the data signal is corresponding to a DMX512 protocol.

17. The decoding method according to claim 15, wherein the step of generating the sample number corresponding to the slot period further comprises:
sampling a first slot of the slots to generate the sample number, wherein the first slot has a start code.

18. The decoding method according to claim 15, wherein the step of generating the sample number corresponding to the slot period further comprises sampling a first slot of the slots to generate the sample number, wherein the first slot has a default code.
